(19) United States
(12) Patent Application Publication
(10) Pub. No.: US 2011/0115047 A1
(43) Pub. Date: May 19, 2011

(54) SEMICONDUCTOR PROCESS USING MASK OPENINGS OF VARYING WIDTHS TO FORM TWO OR MORE DEVICE STRUCTURES

(76) Inventors: Francois Hebert, San Mateo, CA (US); Aaron Gibby, Fitchburg, WI (US); Stephen Joseph Gaul, Melbourne Villiage, FL (US)

(21) Appl. No.: 12/794,236

(22) Filed: Jun. 4, 2010

Related U.S. Application Data
(60) Provisional application No. 61/261,043, filed on Nov. 13, 2009.

(51) Int. Cl. H01L 29/06; H01L 21/02; H01L 21/331; H01L 29/73; H01L 21/306

(52) U.S. Cl. 257/508; 438/386; 438/361; 257/517; 257/544; 438/689; 257/506; 257/E21.008; 257/E21.37; 257/E29.018; 257/E29.02; 257/E29.019; 257/E29.174; 257/E21.215

(57) ABSTRACT

Methods and structures for a semiconductor device can use mask openings of varying widths to form structures of different depths, different materials, and different functionality. For example, processes and structures for forming shallow trench isolation, deep isolation, trench capacitors, base, emitter, and collector, among other structures for a lateral bipolar transistor are described.

### CROSS REFERENCE TO RELATED APPLICATION

This application claims benefit of U.S. Provisional Patent Application Ser. No. 61/261,043 filed Nov. 13, 2009, which is incorporated herein by reference.

### DESCRIPTION OF EMBODIMENTS

The accompanying drawings, which are incorporated in and constitute a part of this specification, illustrate embodiments of the present teachings and together with the description, serve to explain the principles of the present disclosure. In the figures:

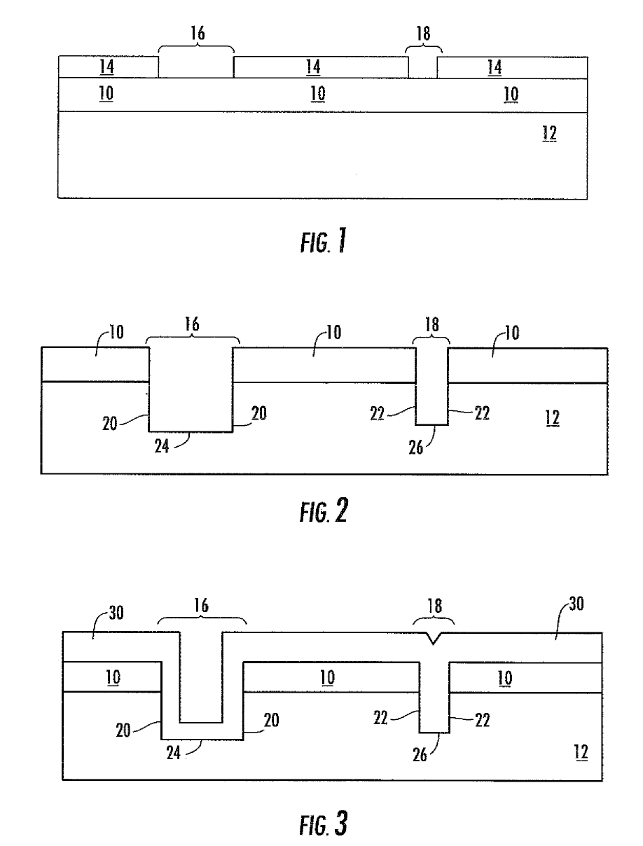

FIGS. 1-30 are cross sections of various intermediate structures which can be formed using embodiments of the present teachings; and

FIG. 31 is a schematic depiction of an electronic system which can include an embodiment of the present teachings.

It should be noted that some details of the FIGS. have been simplified and are drawn to facilitate understanding of the inventive embodiments rather than to maintain strict structural accuracy, detail, and scale.

Reference will now be made in detail to the present embodiments (exemplary embodiments) of the present teachings, examples of which are illustrated in the accompanying drawings. Wherever possible, the same reference numbers will be used throughout the drawings to refer to the same or like parts.

Various embodiments of the disclosure include the formation of two or more structures using a single mask step. For example, a number of structures which can include isolation regions, sinkers, and deep bases for lateral bipolar transistor devices, such as PNP or NPN devices, can be formed using a single mask process. The exemplary description below is in reference to one type of device, for example a lateral PNP device, but it will be understood that devices of the opposite conductivity, for example NPN devices, can be formed using similar processes. An embodiment based on the use of narrow and wide openings which can be patterned at the same time to form openings of differing depths using a single mask step, depending on the initial width of the opening. For purposes of this disclosure, the terms “opening,” “trench,” “recess,” and “groove” are used interchangeably, as the initial shape of each of the two or more trenches or openings, when seen in a plan view, can include one or more of an elongated opening, a circle, an oval, a square, a rectangle, a ring, etc., depending on the final structure being formed.

Further, the terms “wide” and “narrow” when used herein to describe an opening, relate to two or more openings wherein the wide opening is wider than the narrow opening. The terms are used to simplify description of the present teachings, rather than to indicate the size of the openings relative to any structures other than to one or more other openings.

In one exemplary process depicted in FIGS. 1-7, a blanket hardmask 10, for example a first oxide layer having a thickness of about 500 Å to about 10,000 Å, or thicker depending on the depth of the trenches, can be deposited over an underlying layer 12 such as a semiconductor wafer, wafer substrate assembly (substrate), an epitaxial layer, or a combination of two or more layers, then densified. The hardmask layer can also be a multi-layer structure such as on oxide-nitride-oxide (ONO) sandwich including a thin pad oxide (ex. 50 Å to 300 Å oxide) followed by a nitride (ex. 300 Å to 1,500 Å) followed by a thicker oxide (ex. 1,000 Å to 10,000 Å). The addition of the nitride layer can be used as an etch-stop layer for subsequent processing. The underlying layer 12 can include various other layers and structures, doped regions, etc., which can be found in an in-process device as known by one of ordinary skill in the art

A patterned mask 14, such as a trench contact mask having a large critical dimension (CD) to allow a wide, deep trench and a narrow CD for a narrower, shallower trench can be formed to result in the FIG. 1 structure. The patterned mask 14 includes a wide opening 16 and a narrow opening 18.

Next, the patterned mask 14 can be used to etch and pattern the blanket hardmask 10, and the underlying layer 12. In the alternative, the patterned mask 14 can be removed after etching and patterning the blanket hardmask 10, which is then used to etch the underlying layer 12. In either process, the underlying layer 12 is etched using a first etch and the patterned mask 14 is removed to result in the FIG. 2 structure including patterned hardmask 10. The etching can be performed using standard techniques to selectively etch silicon faster than the masking material. The underlying layer (e.g. silicon) is preferably etched vertically (anisotropically). Etching techniques such as plasma etching, reactive ion etching (RIE), magnetically enhanced RIE (MERIE), inductively coupled plasma (ICP), transformer coupled plasma (TCP) etc., can be used. FIG. 2 depicts wide opening 16 and narrow opening 18 opening within the patterned hardmask 10 and the underlying layer 12 resulting from the first etch. It should be noted that, depending on the etching techniques used, the depth of the narrow trench 18 may be shallower than the wider trench 16, for example because of dry etching effects known in the art. Additionally, optional implants can be performed at this point of the process sequence to dope regions such as wide trench sidewalls 20, the narrow trench sidewalls 22, and/or the trench bottom regions 24, 26.

Subsequently, a conformal dielectric layer 30 having a thickness which is at least half the width of the narrow opening 18, for example about 0.7 times the width of the narrow opening, and less than half the width of the wide opening 16, is deposited over the patterned hardmask 10 and the underlying layer 12 to result in the FIG. 3 structure. The conformal dielectric layer 30 can be formed from oxide and will impinge on itself in the narrow opening 18 and will not impinge on itself in the wide opening 16 which, in effect, results in a thicker layer within in the narrow opening 18 than in the wide opening 16. That is, the conformal dielectric layer 30 remains conformal within the first (wide) opening 16, and substantially fills the second (narrow) opening 18 with material by impinging on itself. It will be understood by one of ordinary skill in the art that some material voiding (i.e. “keyholing”) may occur as the conformal dielectric layer 30 impinges on itself. Conformal dielectric layer 30 may be deposited using various techniques such as low pressure chemical vapor deposition (LPCVD), plasma enhanced CVD (PECVD), atmospheric CVD (ACVD), subatmospheric CVD (SACVD), atomic layer deposition (ALD), etc. Although oxide is specifically mentioned, other materials may be appropriate depending on the application, such as oxy-nitrides, silicon-rich oxides, non-silicon based oxides, etc.

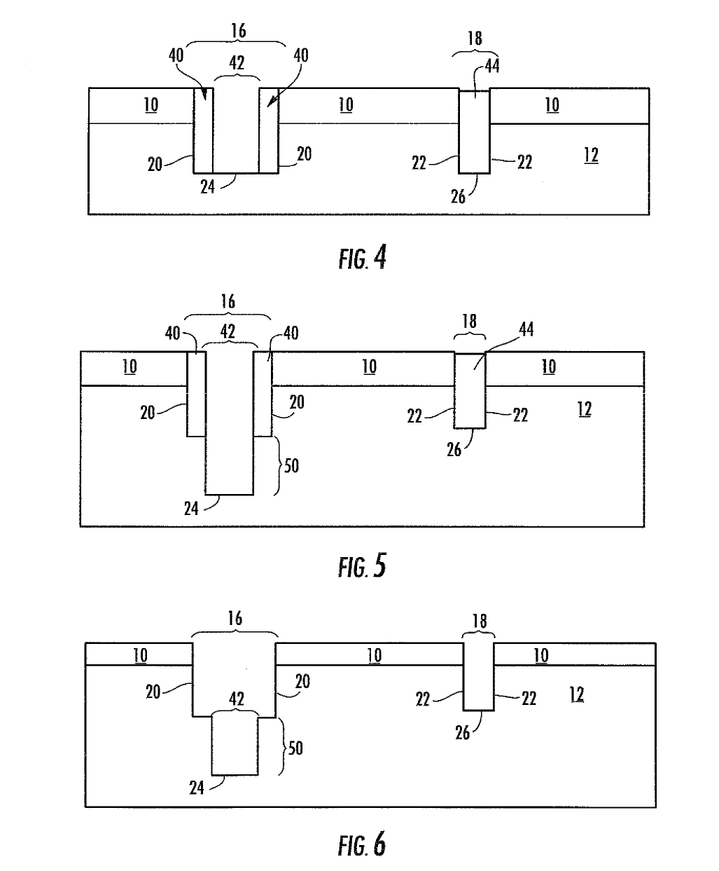

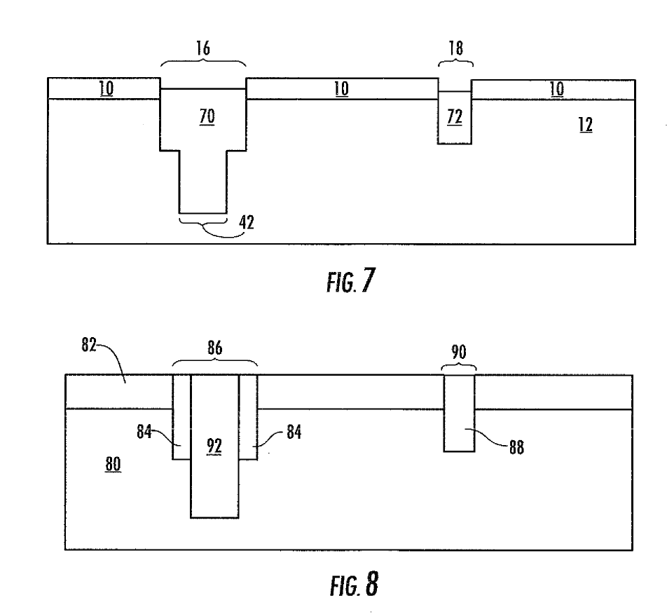

Next, a vertically oriented anisotropic etch can be performed on the FIG. 3 structure to result in dielectric spacers 40 at sidewalls 20 of the wide opening 42, and which may etch and planarize, but not completely remove, the conformal dielectric layer 30 in the narrow opening 18 to result in a dielectric plug 44 as depicted in FIG. 4. Thus dielectric spacers 40 and a dielectric plug 44 are formed from the etched conformal dielectric layer 30. The dielectric spacers 40, in effect, provide a narrower, third opening 42 through the patterned hardmask 10 and into the underlying layer 12 at the location of the wide opening 16. Anisotropic etching of conformal dielectric layer 30 selective to the surrounding underlying layer 12 can be performed using plasma etching, RIE, MERIE, as well as other directional dry etching techniques.

After forming the FIG. 4 structure, a second etch of the underlying layer 12 can be performed through the third opening 42 to transfer the third opening 42 into the underlying layer 12 at location 50. This etch, which may be similar to the silicon etch of underlying layer 12 performed earlier in the process sequence mentioned above, does not significantly etch the underlying layer 12 at the location of the narrow opening 18 and results in a structure similar to that of FIG. 5. Thus the single patterned hardmask 10 formed at the beginning of this process embodiment has been used in two etch processes to form openings which can have at least three different widths (i.e. the wide opening 16 and narrow opening 18 of the first etch, and the opening 42 at location 50 of the second etch) and at least two different depths. At this point, an optional dopant implantation using a material such as boron can be performed into the exposed underlying layer 12. Dopants such as boron (with or without tilt and/or rotation) can be implanted into the exposed bottom and/or sidewalls of the openings to form various structures, such as: P-type isolation regions (in N-doped background regions); one or more conductive sinkers to buried P regions (such as P+ buried layers or P-wells), and/or; deep P-doped regions for high-performance lateral PNP transistors (deep P regions for the collector and emitters). Alternative embodiments which dope the openings with N-type dopants are possible, and anneals may be optionally performed after ion implantation.

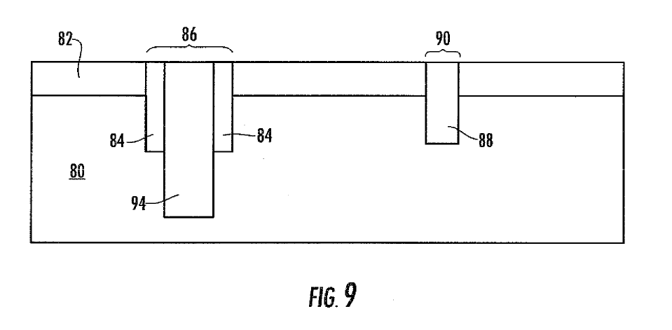

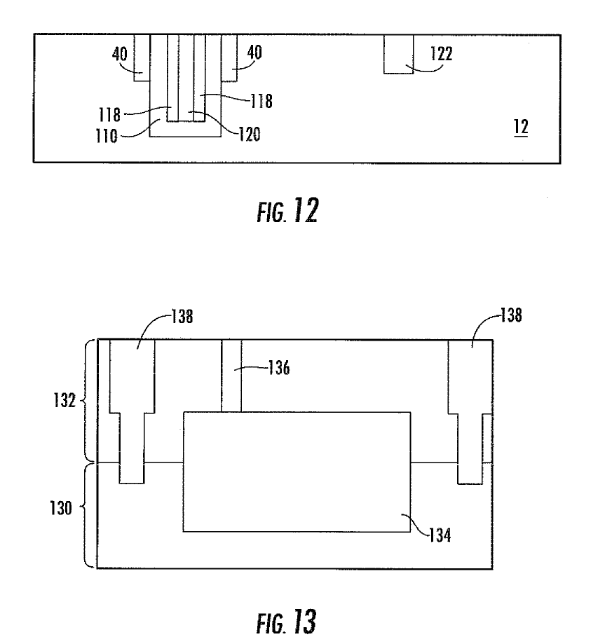

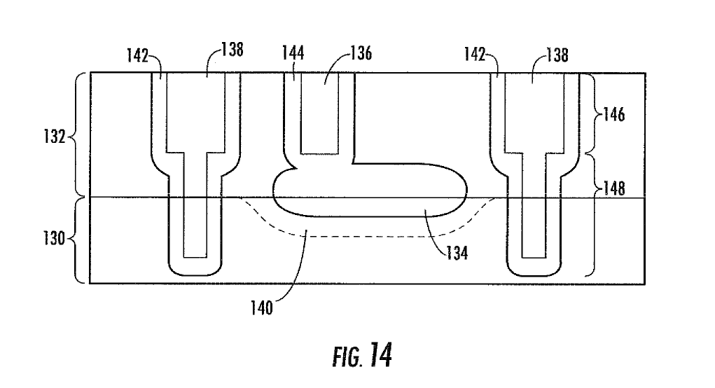

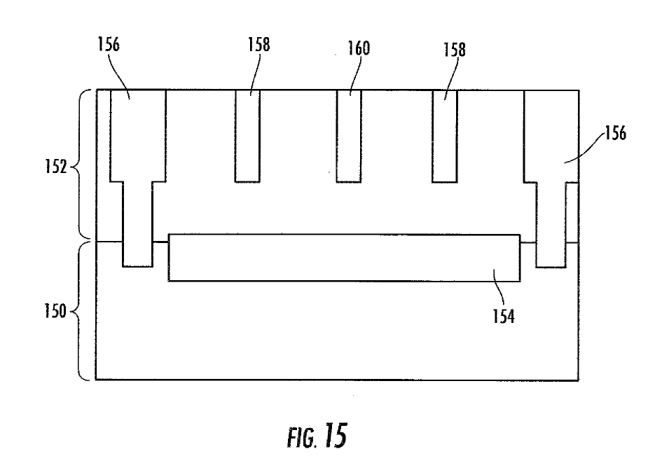

Next, dielectric spacers 40 and dielectric plug 44 can be removed to result in the structure of FIG. 6. This etch can thin, but not completely remove, the patterned hardmask 10. An optional trench bottom and/or sidewall implant can be performed on the FIG. 6 structure to adjust conductivity of the exposed underlying layer 12 as necessary. A thick polysilicon deposition and etchback can be performed using a dry etch such as a reactive ion etch (RIE) or chemical mechanical polishing (CMP) to remove the polysilicon layer from over an upper surface of the semiconductor substrate. This results in the polysilicon structures 70, 72 which remain in the trenches as depicted in FIG. 7. The polysilicon layer used to form polysilicon structures 70, 72 can be formed to have a thickness greater than the half the width of the wider trench such that the polysilicon layer impinges on itself in each of the trenches and avoids a significant dip at the center of the trenches 16, 18, 42. Further, polysilicon structures 70, 72 can be undoped, or doped using, for example, in situ techniques, ion implantation, etc., depending on the application. Next, an oxide etch or CMP can be performed to remove the patterned hardmask 10. Subsequent wafer processing can be performed to result in a completed semiconductor device. This method can be useful, for example, in the formation of a low resistance P+ buried layer (PBL) structure, such as the one depicted in FIGS. 12 and 13, and a bipolar device depicted in FIG. 15, described below in the accompanying text.

Another embodiment is depicted in FIG. 8, and can start with a process similar to that depicted in FIGS. 1-5. After forming a structure similar to that depicted in FIG. 5, a conductively doped or undoped polysilicon layer, which may be conformal, can be deposited and planarized to result in the structure of FIG. 8, which includes an underlying layer 80, a patterned hardmask 82, dielectric spacers 84 at a wide opening 86, a dielectric plug 88 at a narrow opening 90, and polysilicon structure 92 (which can be conductive) as depicted. The conformal dielectric layer 88 within the narrow opening 90 can prevent the formation of the polysilicon layer 92 within the narrow opening 90. The patterned hardmask 82 can be formed from a first oxide layer, while the dielectric spacers 84 and the dielectric plug 88 can be formed from a second oxide layer.

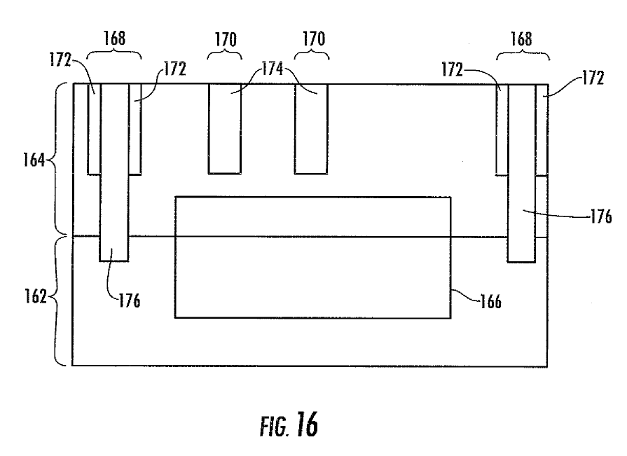

This method can be useful in forming a structure including shallow trench isolation (STI) formed from plug 88 in the shallow, narrow trench 90, and a deeper polysilicon isolation formed from polysilicon structure 92 formed in the wider trench 86. Such a structure is depicted in FIG. 16 and described below in the accompanying text. The dielectric spacers 84 can prevent contact between the polysilicon structure 92 and an upper portion of the semiconductor substrate 80.

Another embodiment similar to that depicted in FIG. 8, depicted in FIG. 9, can include the formation of a dielectric structure 94 instead of the polysilicon structure 92 of FIG. 8. Dielectric structure 94 can be formed from a third oxide layer. Thus the completed structure can include the elements depicted in FIG. 8, except that structure 94 of FIG. 9 can include an oxide or another dielectric material such as silicon nitride, etc. Subsequently, the patterned hardmask 82 can be etched back using CMP or a planarizing wet or dry etch which removes all exposed materials at about the same rate. This method can be useful for forming shallow trench isolation (STI) 88 in the narrower trench 90 and deeper isolation 84, 94 in the wide trench 86. A structure which uses the method of FIG. 9 is depicted in FIG. 17, which is described in the accompanying text below.

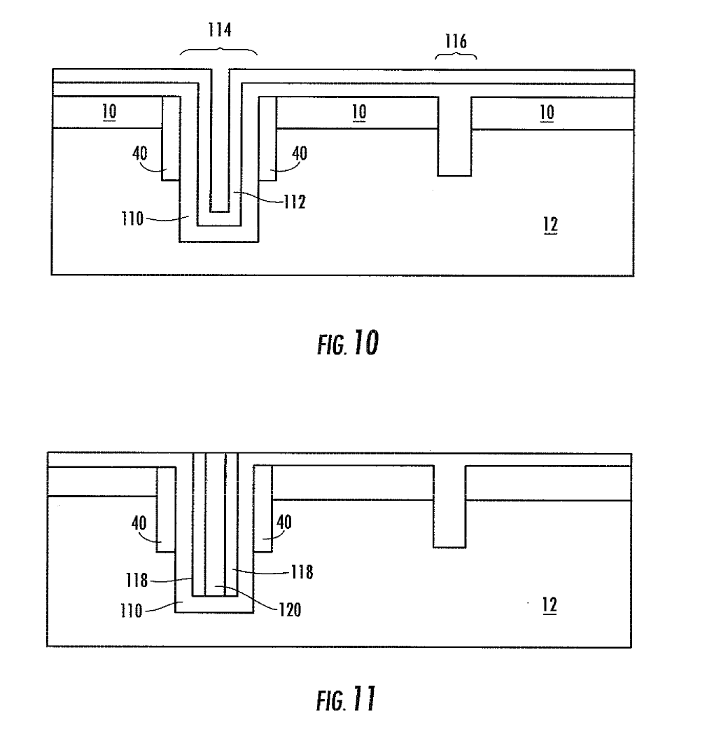

Another exemplary embodiment is depicted in FIGS. 10-12. This embodiment can begin with formation of the FIG. 5 structure in accordance with the embodiment depicted in FIGS. 1-5. After forming a structure similar to that depicted in FIG. 5, a conformal oxide layer 110 or another dielectric is formed, followed by formation of a conformal polysilicon layer 112. In an exemplary embodiment, a wide trench 114 can have a width from about 5,000 Å to about 15,000 Å wide, and a narrow trench 116 can have a width from about 2,000 Å to about 10,000 Å wide. Conformal oxide 110 can be formed to a thickness from about 1,200 Å to about 7,000 Å, and conformal polysilicon 112 can have a thickness from about 3,000 Å to about 15,000 Å. The conformal oxide layer 110 is formed to a thickness sufficient to impinge on itself and fill the narrow opening 116, while both the conformal oxide layer 110 and conformal polysilicon layer 112 do not impinge on themselves and form conformally within in the wide opening 114.

An anisotropic (vertical) spacer dry etch can be performed which etches the conformal polysilicon layer 112 selective to the conformal oxide layer 110 to remove the conformal polysilicon layer 112 from horizontal surfaces to result in the polysilicon spacers 118 as depicted in FIG. 10. Next, a conformal oxide deposition followed by a planarization can be performed to leave an oxide plug 120 filling the opening in the wide trench as depicted in FIG. 11. The planarization can be continued (or other method steps can be performed) to remove portions of conformal dielectric 110 and patterned hardmask 10 to result in the structure of FIG. 12, including oxide plug 122 in narrow opening 116. The polysilicon spacers 118 can be used as two parallel plates of a capacitor, with oxide plug 120 providing capacitor dielectric. In this embodiment, plug 122 can be used as STI, and conformal oxide layer 110 electrically isolates the first and second capacitor plates 118 from the underlying layer (i.e. the semiconductor substrate 12).

It will be evident to one of ordinary skill in the art that the processes and resulting structures previously described can be modified to form various semiconductor device features having different patterns, widths, and/or materials using a single mask step. Exemplary methods and resulting structures are described below.

FIG. 13 depicts a substrate 130, such as a silicon wafer, and an epitaxial layer 132 formed over the substrate 130. It will be understood that in an alternative embodiment, the substrate 130 and epitaxial layer 132 can instead be a single semiconductor layer, with the epitaxial layer 132 being a doped region within the substrate. FIG. 13 further depicts a doped P+ buried layer (PBL) 134, for example formed using a masked implant at a sufficient energy to bury the implant. Also depicted is a narrow and shallow polysilicon contact (sinker) 136 which electrically contacts the PBL 134 and P+ polysilicon isolation structures 138.

The polysilicon contact 136 and P+ polysilicon isolation structures 138 can be formed using a single mask process according to the techniques described above. A wide opening in a mask and spacers are used to form polysilicon isolation structures 138, while a narrow opening in the mask is used to form polysilicon contact 136. Further, the polysilicon sinker 136 and at least part of the polysilicon isolation structures 138 can be formed from the same polysilicon layer.

It should be noted that, as used herein, the phrases “the same layer,” “the same dielectric layer,” “the same conductive layer,” etc. refer to material at two or more locations which have been simultaneously formed as a layer during a fabrication process.

The cross section of FIG. 14 depicts details of the FIG. 13 structure. FIG. 14 can include a P-type semiconductor substrate 130, for example a semiconductor wafer, and an N-type epitaxial layer 132. An implanted N-buried layer 140 is formed within the P-type substrate 130, then the PBL 134 is implanted into the N-type epitaxial layer 132 and the N-buried layer 140. After forming a P-doped polysilicon layer 136, 138 within the openings, P-type ions diffuse out of the polysilicon isolation structures 138 to provide P-diffusion 142, and P-type ions diffuse out of the polysilicon contact 136 to form P-diffusion 144.

FIGS. 13 and 14 depict a structure in which the P+ polysilicon sinker 136 contacts the PBL 134 at a first depth within the semiconductor layer, and is exposed at the upper surface of the semiconductor layer 132. Further, the two polysilicon structures 138 and the P-diffusion 142 provide isolation structures within the semiconductor layer 132 which are located laterally on either side of the PBL 134, such that the PBL 134 is interposed directly between the two isolations provided by 138, 142. Each isolation region includes a first portion 146 having a first horizontal width and a second portion 148 having a second horizontal width which is narrower than the first width. The first portion 146 of each isolation region 138 extends from the upper surface of the semiconductor layer 132 to a first depth, and the second portion 148 extends from the first depth to the lateral location with respect to the doped buried layer 134. FIG. 15 depicts a structure including a semiconductor substrate 150 and an epitaxial layer 152, although a well region within a semiconductor layer can be used instead of the epitaxial layer 152. FIG. 15 further depicts an N+ buried layer (NBL) 154 formed within the substrate 150 and the epitaxial layer 152. These structures can be used to form, for example, a high-performance bipolar semiconductor device such as a lateral PNP device using an embodiment including the techniques described above.

In an embodiment, two wide openings and three narrow openings are formed within a single mask layer using techniques previously described, and the process is continued to provide a planarized polysilicon layer, for example a P+ doped single planarized conformal polysilicon, to provide polysilicon within wide and narrow openings as depicted. In this embodiment, polysilicon 156 within the wide openings provides P+ polysilicon isolation material. The P+ polysilicon within the narrow openings forms P+ polysilicon collectors 158 and a P+ polysilicon emitter 160. Other structures as necessary are formed to provide structures for a lateral PNP device.

Thus the two isolation structures 156, the two PNP device collectors 158, and the PNP device emitter 160 are formed using a process including only one mask and only one polysilicon layer. A deep base for the PNP device is provided by the collectors 158 and the emitter, the isolation is formed by the material 158 within the wide openings defined by the mask layer. The N+ buried layer 154 is useful to isolate the lateral PNP. The N+ buried layer 154 can also be useful to reduce or eliminate parasitic vertical bipolar structures formed between the substrate 150 and the lateral PNP collector 158 and emitter 160 regions, as known in the art.

It should be noted that two or more openings depicted in cross section may be two different portions of the same opening, for example if the opening is formed in a square, rectangular, or circular shape. For example, in FIG. 15, the two narrow openings into which material 158 is formed may be two portions of the same opening formed in a ring shape to surround the opening into which material 160 is formed. Thus material 158 may completely encircle material 160, or may surround material 160, for example on three sides. Thus while FIG. 15 is described as having three narrow openings into which materials 158, 160 are formed, it will be understood that the description of three openings will encompass this embodiment where both structures 158 are formed in a single trench formed in a ring, square, rectangle, “U” shape, etc. It should be further noted that, in an embodiment, a resulting lateral PNP transistor including the device collectors 158 and the device emitter 160 can be more compact than standard structures. This may result since deep emitter and collector regions can be formed with a small open area. Also, the resulting lateral PNP may achieve higher performance (higher current gain, improved high-current carrying capabilities, etc.) than standard lateral PNP devices, resulting from the high aspect ratio of the emitter and source, and because of the high doping of these emitter and source regions.

FIG. 16 depicts two different types of isolation structures which can be formed using the techniques of the present teachings, for example as depicted in FIGS. 1-5 and 8. For purposes of illustration, the isolation structures are formed within a semiconductor substrate 162 such as a semiconductor wafer and an epitaxial layer 164. As with some prior embodiments, a doped buried layer 166 can be implanted into the semiconductor substrate 162 and/or the epitaxial layer 164, depending on the eventual use.

In this embodiment, a mask having two wide opening and two narrow openings is formed, which is used to etch the epitaxial layer 164 and the semiconductor substrate 162 according to techniques discussed above. This forms wide openings 168 within layers 164 and 162, and narrow openings 170 within layer 164. A conformal dielectric layer such as oxide is formed to impinge on itself within the narrow openings 170 and to not impinge on itself within the wide openings 168. Subsequently, a vertically oriented anisotropic etch forms dielectric spacers 172 within the wide trench 168 and dielectric plugs 174 within the narrow openings.

Subsequently, an etch which removes exposed portions of the epitaxial layer 164 and semiconductor substrate 162 selective to the dielectric spacers 172 and the dielectric plugs 174 is used to deepen (i.e., increase the depth of) the opening at the wide openings 168. The mask is removed and a conformal conductive layer of a material such as polysilicon is formed and planarized to result in the structure depicted in FIG. 16, including conductive polysilicon 176 at the location of the wide openings 168.

In this embodiment, dielectric plugs 174 form dielectric isolation within the narrow openings 170, and conductive polysilicon 176 forms conductive isolation which is electrically isolated from the upper surface of the epitaxial layer 164 by dielectric spacers 172. All of the wide openings 168, the narrow openings 170, the dielectric plugs 174 (often referred to as “shallow trench isolation” or “STI), the dielectric spacers 172, and the conductive isolation 176 are formed using only one mask. The conductive isolation 176 is formed to a sufficient depth to contact the substrate (i.e. a semiconductor wafer, wafer section, epitaxial layer, etc.) 162. The doped buried layer 166 is directly interposed between the conductive layer 176 within the lower portion of openings 168, and is not directly interposed between the dielectric layer 172 within openings 168. The dielectric layer within openings 174 directly overlies the doped buried layer 166.

FIG. 17 depicts an embodiment in which both deep and shallow isolation can be formed using a single mask. For exemplary purposes, this embodiment is formed using the same process as that of FIG. 16 except that, instead of forming conductive polysilicon structures 176, another dielectric layer 178 is formed to provide deep dielectric isolation down to the semiconductor substrate 162. Thus FIG. 17 depicts semiconductor substrate 162, epitaxial layer 164, implanted buried layer 166, wide openings 168, narrow openings 170, dielectric spacers 172, dielectric plugs (STI) 174, and dielectric layer 178. Dielectric spacers 172 and dielectric layer 178 together form a wider isolation at the upper half of the epitaxial layer 164, and the dielectric layer 178 forms a narrower isolation at the lower half of the epitaxial layer 164 and within the semiconductor substrate 162. Dielectric layer 178 thus provides deeper isolation around the implanted buried layer 166. The buried layer 166 is directly interposed between the dielectric layer 178 formed within openings 168, and the dielectric layer 174 formed within openings 170 directly overlies the doped buried layer 166. More compact isolation can be obtained using dielectrics such as oxide, for example because no depletion layers will be formed in the semiconductor regions when dielectrics are used. When polysilicon is used (as in 176 in FIG. 16), PN junctions are formed which can result in depletion layers, which can require larger lateral spacing.

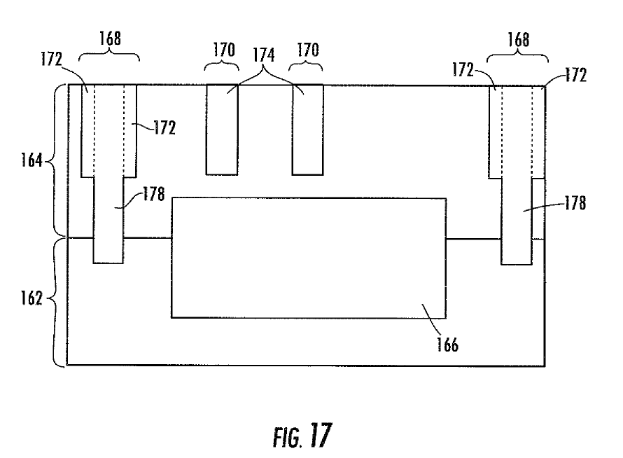

FIGS. 18-24 depict embodiment to form an integrated trench capacitor structure including deep isolation formed using a dielectric in a wider trench, STI formed using a dielectric in a narrower trench, and polysilicon capacitor plates which can be formed in a wider trench using alternating oxide, polysilicon, oxide depositions and an anisotropic polysilicon etch after a polysilicon deposition. These materials are exemplary, and different or additional materials such as silicide may also be used.

In the exemplary embodiment, a structure including a semiconductor substrate 180 and an epitaxial layer 182 is provided. A patterned mask 184 such as photoresist is used to etch a hardmask such as a densified oxide to provide a patterned hardmask 186. The patterned hardmask 186 can include three openings as depicted in FIG. 18, a first opening 188, a second opening 190 which is wider than the first opening 188, and a third opening 192 which is wider than both the first opening 188 and the second opening 190. In the embodiment depicted, the first opening 188 is two arbitrary units (i.e. “units”) wide, the second opening 190 is four units wide, and the third opening 192 is seven units wide. The widths of the three openings are exemplary.

After forming the FIG. 18 structure, a first etch of the exposed epitaxial layer 182 is performed to transfer the three openings from the patterned hardmask 186 to the epitaxial layer 182 as depicted in FIG. 19. Optional doping of exposed epitaxial layer 182 can be performed at this time. Subsequently, a first conformal dielectric layer 194 such as silicon oxide or silicon nitride is formed. In this embodiment, the first conformal dielectric layer 194 is one unit thick so as to impinge on itself within the first opening 188 and to not impinge on itself in the second opening 190 or the third opening 192 as depicted in FIG. 19. The layer may be formed more thickly than half the width of the first opening 188, but less than half the width of the second opening 190, to avoid an excessive dip at the center of the opening.

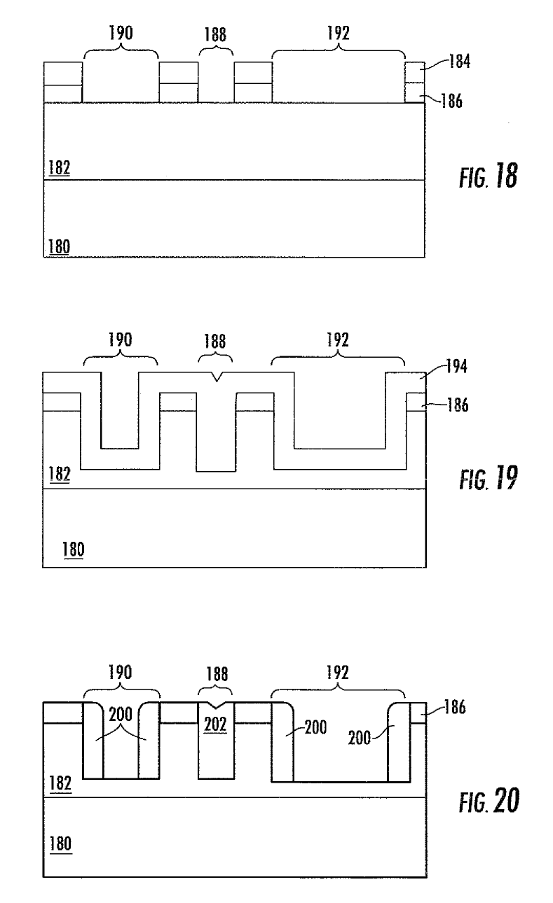

Next, a vertical anisotropic second etch is performed to remove dielectric layer 194 selective to the patterned hardmask 186 and the epitaxial layer 182 to result in the structure of FIG. 20. The vertical anisotropic etch forms dielectric spacers 200 in the second opening 190 and the third opening, and a dielectric plug 202 which can provide shallow trench isolation (STI) in the first opening 188. Optional doping in the exposed epitaxial layer 182 can also be performed at this time. It should be noted that the doping can be used to form portions of device structures such as drain extensions of lateral DMOS devices, or it can be used to control parasitic field threshold regions. The doping can also be part of the isolation scheme.

Subsequently, a vertical anisotropic third etch is performed to remove the epitaxial layer 182 and the semiconductor substrate 180 selective to the hardmask 186 the dielectric spacers 200, and the dielectric plug 202 to result in the FIG. 21 structure.

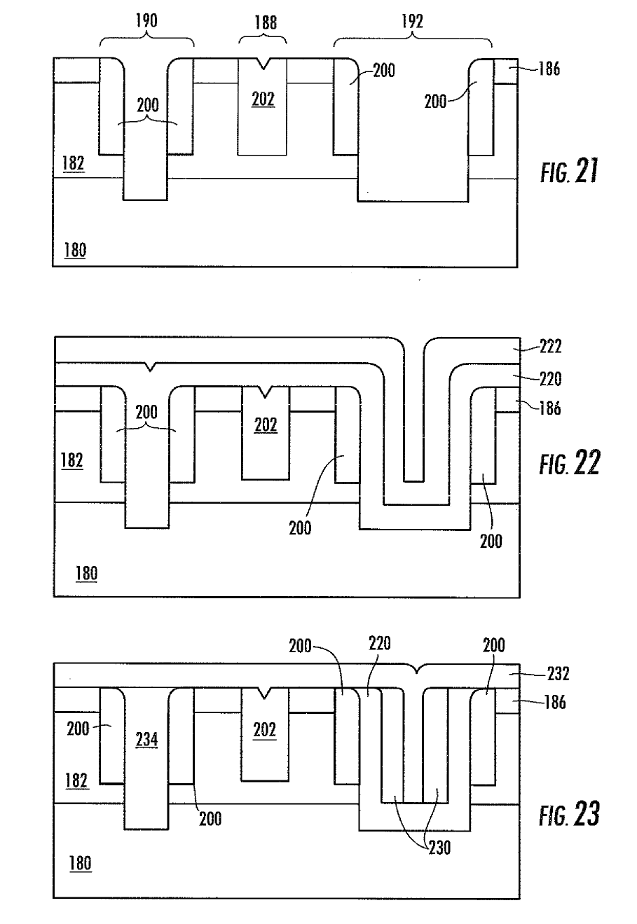

After forming a structure similar to FIG. 21, a conformal dielectric layer 220 then a conformal conductive layer 222, each one unit thick as depicted in FIG. 22, are formed. The conformal dielectric layer 220 impinges on itself within the second opening 190, and does not impinge on itself in the third opening 192. Layer 220 can include one or more dielectric layers, and conductive layer 222 can include one or more polysilicon layers and/or metal layers, for example.

Subsequently, the conformal conductive layer 222 can be etched selective to the dielectric layer 220 to form conductive spacers 230 as depicted in FIG. 23. Then, the dielectric layer 220 can be planarized down to the hardmask 186 to form a dielectric plug 234 within opening 190. In the alternative, a single etch can be performed which removes both the conductive layer 222 and the dielectric layer 220, as long as dielectric 200 and 202 is not etched below the level of the bottom of the hardmask 186. Subsequently, another dielectric layer, such as a high-quality capacitor dielectric layer 232 is formed as depicted in FIG. 23. This dielectric layer 232 can be formed one unit thick to impinge on itself in the remaining opening at location 192.

Next, the FIG. 23 structure is planarized, for example using a chemical mechanical polishing (CMP) process, to result in the FIG. 24 structure.

In the process of FIGS. 18-24, only one patterned photoresist mask layer 184 is used to form the following structures as depicted in FIG. 24: an STI structure from plug 202 at opening 188; a wider, deeper isolation structure from dielectric spacers 200 and dielectric plug 234 at opening 190; and a capacitor including two conductive plates 230 and capacitor dielectric 232 at opening 192. A first dielectric layer forms the dielectric spacers 200 at 190 and 192, and the dielectric plug 202 at 188. A second dielectric layer forms the dielectric plug 234 and dielectric structure 220, and a third dielectric layer forms capacitor dielectric 232 at location 192. It should be noted that, depending on the shape of opening 192, a separate patterned etch may be needed to separate layer 222 (FIG. 22) into separate capacitor plates (230, FIG. 24). Opening 192 may form a closed figure such as a rectangle when viewed from above and, in this instance, the ends of the layer can be etched to separate the conductor 222 into separate portions 230.

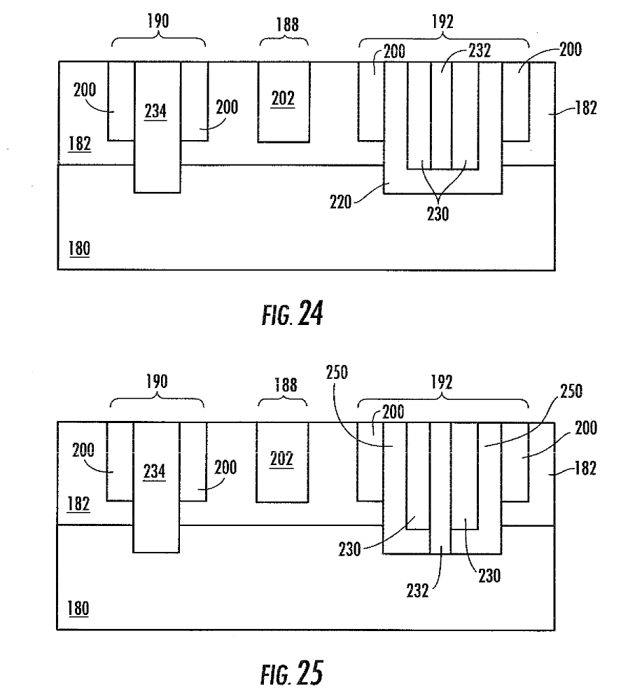

FIG. 25 depicts an alternate process which is similar to the one used to form the FIG. 24 structure. In the process, after etching conductive layer 222 to form conductive spacers 230 depicted in FIG. 23, the dielectric layer 220 of FIG. 22 can be etched to expose the semiconductor substrate 180. The process continues in accordance with that used to form the FIG. 24 structure. In this embodiment, conformal dielectric layer 220 of FIG. 22 can be etched at the bottom of opening 192 to form dielectric spacers 250, and capacitor dielectric layer 232 of FIG. 23 can physically contact the semiconductor substrate 180 as depicted by capacitor dielectric 252 of FIG. 25.

Various aspects of the one or more embodiments can include the following elements:

A typical narrow trench can be of the order of about 0.1 to about 1 micron in range, to achieve a depth in the 0.5 to 10 micron range. An aspect ratio of up to 10:1 or more is possible with appropriate trench etch tool.

Typically, the dielectric which is formed to impinge on itself in the narrow trench and not impinge on itself in the wider trench will have a thickness which is about 2.5 to about 4.0 times the width of the narrow trench, and less than half the width of the wide trench.

The width of the wider trench will typically be more than about 2.5 times the thickness of the dielectric which impinges on itself in the narrow trench. For example, for a 0.5 micron narrow trench, the dielectric should be at least about 0.3 to about 0.4 microns thick to fill the narrow trench without a gap. Therefore, the wider trench should be more than about 2.5 times the deposited oxide, or greater than approximately 0.9 microns.

A single mask can be used to form narrow-shallow and wide-deep trenches at the same time.

Trenches can be filled with doped polysilicon to act as connections, junction isolation, sinkers and junctions of “deep-base” lateral-PNP structures.

Deep trench isolation and shallow trench isolation (STI) can be formed using only one mask.

A deep trench can be oxide filled or polysilicon filled using a process which also forms an oxide sidewalk in an upper portion of the trench.

Alternating oxide/polysilicon/oxide depositions with an anisotropic polysilicon etch can be used to form capacitor integrated with trench flow.

In the embodiment of FIGS. 18-24 and other embodiments, the openings can include three (or more) trenches having different widths. The three (or more) trenches having three (or more) widths can be formed with a single mask to form openings having three (or more) depths. For example, the structure of FIG. 21 can be formed according to the process described above using a first etch to etch the underlying layer 182 to form the first trench 188, the second trench 190, and the third trench to a first depth. A second etch through the second trench 190 and the third trench 192 etches the underlying layer at the second trench and at the third trench to a second depth deeper than the first depth. The second etch also forms the plug 202 within the first trench and spacers 200 within the second trench 190 and the third trench 192.

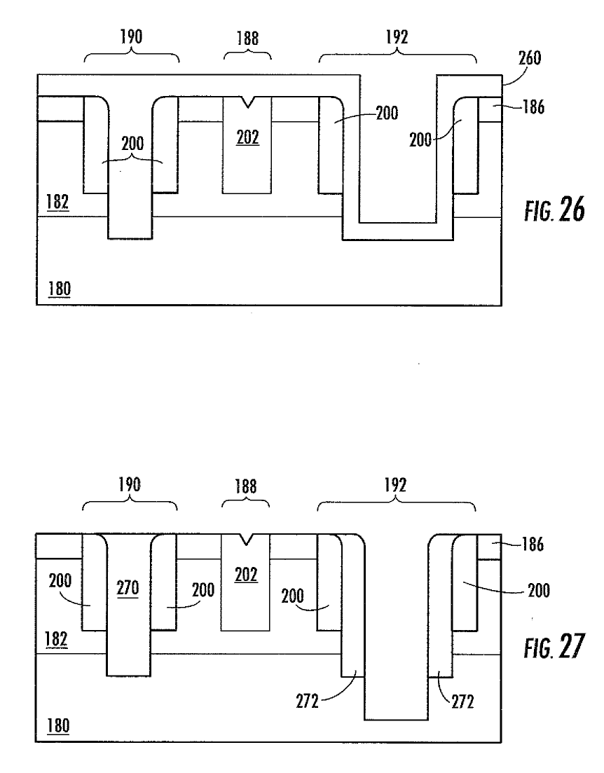

After forming the FIG. 21 structure, the process can then continue as depicted in FIGS. 26-30. A second conformal layer 260, such as a dielectric layer, is formed as depicted in FIG. 26. The second conformal layer 260 is formed over the plug 202 which is within the first opening 188, impinges on itself within the second opening 190 to fill the second opening 190 with dielectric, and forms conformally within the third opening 192.

Next, a third etch is performed on the FIG. 26 structure. The third etch etches the exposed underlying layer 180, 182 through the third trench to result in a structure similar to that depicted in FIG. 27. The second conformal layer is etched to form a second plug 270 within the second trench 190 and spacers 272 within the third opening 192. The etch is continued at the third trench 192 to etch the epitaxial layer 182 and the semiconductor substrate 180 through the third trench 192. This etch deepens the third trench to a third depth deeper than the first and second depths.

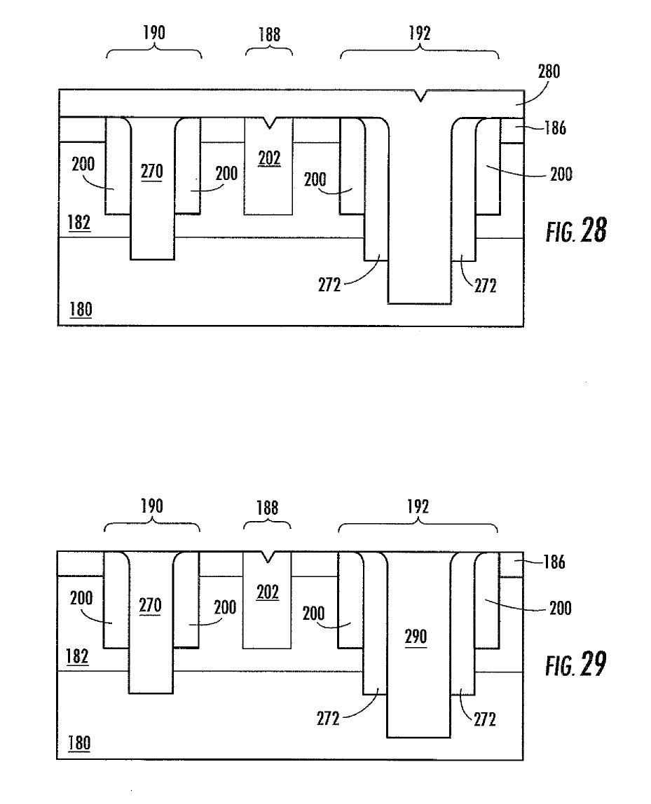

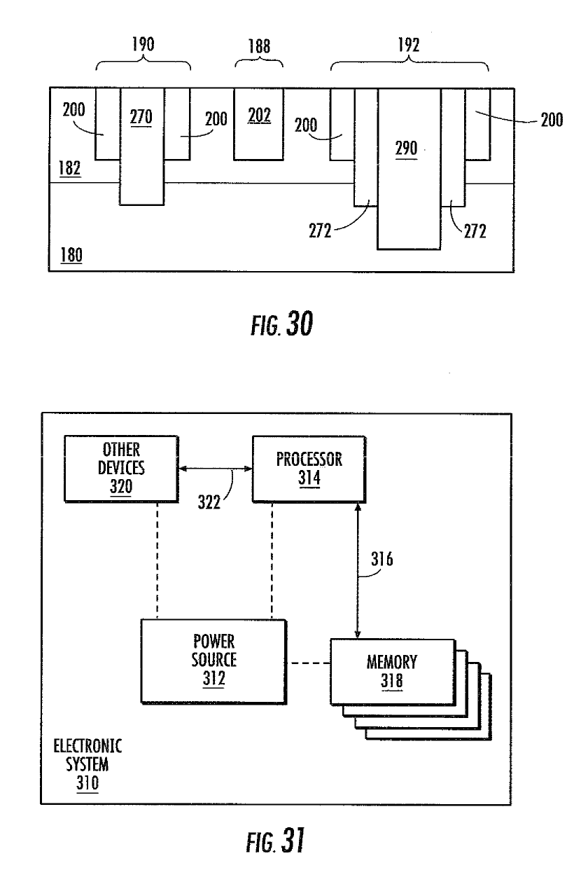

The process can continue according to the particular use. For example, a third conformal layer 280 as depicted in FIG. 28 can be formed to a thickness sufficient to impinge on itself within the third trench 192, and is formed over the first plug 202 and the second plug 270. The upper surface of the FIG. 28 structure can be etched to stop on the hardmask 186 as depicted in FIG. 9 to result in a third plug 290 within the third trench 192. The etch can further continue to remove the hardmask 186 and result in the structure of FIG. 30.

Thus this process can form a first opening 188 having a first depth within the underlying layer 182, a second opening 190 having a second depth deeper than the first depth, and a third opening 192 deeper than the first and second depths. The three openings within the underlying layer having three different depths are formed using one patterned mask. It will be understood that any number of different trench widths and depths can be formed using variations on this process. Various other combinations are also contemplated.

Thus embodiments of the present teachings can reduce the number of required masking steps during the manufacture of semiconductor devices. Using a lower number of masks simplifies the manufacturing process, increases yields, and reduces wafer and equipment costs and cycle time for fabrication and, therefore, the cost to produce a completed semiconductor device. Embodiments of the present teachings can be used for example, to form isolation structures, sinkers to underlying regions, and deep base diffusions used with lateral-PNP transistors (for example to form deep collector and emitter regions). These structures can be formed during the manufacture of various types of semiconductor devices, such as integrated circuit technology for power management and analog applications, as well as others. These devices can be formed using technologies such as bipolar complementary metal oxide semiconductor (BiCMOS) technology, BIPOLAR technologies, complementary bipolar (CBIP) technologies, complementary MOS (CMOS) technologies, double diffused MOS (DMOS) technology, complementary double diffused (CDMOS) technologies, etc.

In a particular embodiment depicted in the block diagram of FIG. 31, an electronic system 310 can include a power source (power supply) 312, which may be a converted AC power source or a DC power source such as a DC power supply or battery. System 310 can also include a processor 314, which may be one or more of a microprocessor, microcontroller, embedded processor, digital signal processor, or a combination of two or more of the foregoing. The processor 314 can be electrically coupled by a bus 316 to memory 318. The bus 316 may be one or more of an on chip (or integrated circuit) bus, e.g. an Advanced Microprocessor Bus Architecture (AMBA), an off chip bus, e.g. a Peripheral Component Interface (PCI) bus, or PCI Express (PCIe) bus, or some combination of the foregoing. The memory 318 can be one or more of a static random access memory, dynamic random access memory, read only memory, flash memory, or a combination of two or more of the foregoing. The processor 314, bus 316, and memory 318 my be incorporated into one or more integrated circuits and/or other components. The electronic system 310 can include other devices 320 such as other semiconductor devices or subsystems including semiconductor devices, and can be coupled to the processor 314 through a bus 322. Any or all of the processor 314, the memory 318 and/or the other devices 320 can be powered by the power source 312. Any or all of the semiconductor devices included as a part of the electronic system 310 or which interfaces with the electronic system 310 can include one or more embodiments of the present teachings. Electronic systems can include devices related to telecommunications, the automobile industry, semiconductor test and manufacturing equipment, consumer electronics, or virtually any piece of consumer or industrial electronic equipment.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

While the present teachings have been illustrated with respect to one or more implementations, alterations and/or modifications can be made to the illustrated examples without departing from the spirit and scope of the appended claims. In addition, while a particular feature of the present disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the methods and structures disclosed herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method used during the formation of a semiconductor device, comprising:
forming a mask over an upper surface of an underlying layer, wherein the mask comprises a first opening therein and a second opening therein, wherein the first opening is wider than the second opening;
etching the underlying layer through the first and second openings to form a first trench having a first width in the underlying layer and a second trench having a second width in the underlying layer, wherein the first trench is wider than the second trench;
forming a conformal layer over the underlying layer and within the first and second trenches, wherein the conformal layer does not impinge on itself in the first trench and impinges on itself in the second trench;
with the conformal layer in the first and second trenches exposed, etching the conformal layer with a second etch to expose the underlying layer at the first trench, wherein the underlying layer at the second trench is not exposed during the second etch; and
with the conformal layer in the second trench exposed, etching the underlying layer with a third etch to increase a depth of the first trench wherein, subsequent to performing the third etch, the first trench is deeper than the second trench.

2. The method of claim 1, further comprising:
forming a dielectric layer within the first trench and over the second trench; and
planarizing the dielectric layer wherein, subsequent to planarizing the dielectric layer, the dielectric layer remains in the first trench.

3. The method of claim 1, further comprising:
forming a conductive layer in the first trench and over the second trench; and
planarizing the conductive layer wherein, subsequent to planarizing the conductive layer, the conductive layer remains in the first trench.

4. The method of claim 1 wherein the conformal layer is a first conformal dielectric layer and the method further comprises:
forming a second conformal dielectric layer within the first trench and over the second trench;
forming a conformal conductive layer within the first trench, over the second conformal dielectric layer, and over the second trench;
anisotropically etching the conformal conductive layer to form a first conductive portion and a second conductive portion, wherein the first and second conductive portions are electrically isolated from each other; and
forming a capacitor dielectric layer between the first and second conductive portions,
wherein the first conductive portion is a first plate of a capacitor, the second conductive portion is a second plate of the capacitor, and the capacitor dielectric is a capacitor dielectric of the capacitor.

5. The method of claim 4, wherein the first conformal layer in the second trench is shallow trench isolation.

6. The method of claim 5 wherein the second conformal dielectric layer in the first trench electrically isolates the first and second capacitor plates from the underlying layer.

7. The method of claim 1, wherein the conformal layer is a conformal dielectric layer and the method further comprises:
forming dielectric spacers from the conformal dielectric layer during the third etch; and
subsequent to performing the third etch, forming a conformal conductive layer within the first trench, wherein the conformal dielectric layer within the second trench prevents the formation of the conformal conductive layer within the second trench.

8. The method of claim 7, further comprising:
removing the conformal conductive layer from the upper surface of the underlying layer wherein, subsequent to removing the conformal conductive layer from the upper surface of the underlying layer, the conformal dielectric layer electrically isolates the conformal conductive layer from an upper region of the underlying layer, and wherein the conformal dielectric layer does not electrically isolate the conformal conductive layer from a lower region of the underlying layer.

9. The method of claim 1, wherein the conformal layer is a first conformal conductive layer and the method further comprises:
forming conductive spacers from the first conformal conductive layer during the third etch; and
subsequent to performing the third etch, forming a second conformal conductive layer within the first trench, wherein the first conformal conductive layer within the second trench prevents the formation of the second conformal conductive layer within the second trench.

10. A method used during the formation of a semiconductor device comprising a lateral bipolar transistor, the method comprising:
forming a mask layer over a semiconductor substrate, wherein the mask layer comprises a first, second, and third openings each having a first width, and fourth and fifth openings each having a second width which is wider than the first width, and the openings expose the semiconductor substrate;
etching the semiconductor substrate through each of the openings to a first depth to form first, second, third, forth, and fifth trenches in the semiconductor substrate;
forming a conformal layer within each of the trenches such that the conformal layer impinges on itself within the first, second, and third trenches, and does not impinge on itself within the fourth and fifth trenches;
anisotropically etching the conformal layer to expose the semiconductor substrate at the fourth and fifth trenches, wherein the anisotropic etch does not expose the semiconductor substrate at the first, second, and third trenches;
after anisotropically etching the conformal layer, etching the semiconductor substrate through the fourth and fifth trenches to a second depth which is deeper than the first depth; and
forming a conductive layer within each of the trenches,
wherein the conductive layer within the first and second trenches is adapted to function as collectors for the lateral bipolar transistor, the conductive layer within the third trench is adapted to function as an emitter for the lateral bipolar transistor, and the conductive layer and the second conformal layer within the fourth and fifth trenches are adapted to function as device isolation structures for the lateral bipolar transistor.

11. The method of claim 10, further comprising:
after anisotropically etching the conformal layer, removing the conformal layer from the fourth trench and from the fifth trench.

12. The method of claim 11, wherein forming the conductive layer within each of the trenches comprises:
forming the conductive layer to a thickness sufficient to impinge on itself within each of the trenches; and
removing the conductive layer from over an upper surface of the semiconductor substrate and leaving the conductive layer within each of the trenches.

13. A semiconductor device, comprising:
a semiconductor layer having an upper surface;
a doped buried layer located below the upper surface of the semiconductor layer;
a conductive sinker contacting the doped buried layer at a first depth within the semiconductor layer and exposed at the upper surface of the semiconductor layer; and
at least one isolation region within the semiconductor layer and comprising a first portion having a first width which extends from the upper surface of the semiconductor layer to the first depth and a second portion having a second width narrower than the first width which extends from the first depth to a lateral location with respect to the doped buried layer,
wherein the conductive sinker and at least a portion of the at least one isolation region comprise the same layer.

14. The semiconductor device of claim 13 wherein the same layer is a first conductive layer and the at least one isolation region further comprises:
a second conductive layer formed below the upper surface of the semiconductor layer, wherein the conductive sinker does not comprise the second conductive layer.

15. A lateral bipolar transistor, comprising:
a semiconductor substrate comprising at least first, second, and third openings each having a first width and a first depth, and fourth and fifth openings having a second width which is wider than the first width and a second depth which is deeper than the first depth; and
a conductive layer within the each of the openings, wherein the conductive layer within each of the openings comprises the same conductive layer,
wherein the conductive layer within the first and second openings is adapted to function as collectors for the lateral bipolar transistor, the conductive layer within the third opening is adapted to function as an emitter for the lateral bipolar transistor, and the conductive layer within the fourth and fifth openings is adapted to function as device isolation structures for the lateral bipolar transistor.

16. The lateral bipolar transistor of claim 15, further comprising a doped buried layer within the semiconductor substrate, wherein the conductive layer in the first, second, and third openings overlies the doped buried layer, the doped buried layer is directly interposed between the conductive layer within the fourth and fifth openings, and the doped buried layer is not directly interposed between the conductive layer within the fourth and fifth openings.

17. A semiconductor device, comprising:
a semiconductor substrate having at least one first opening therein, wherein the at least one first opening comprises a first width, a first depth, an upper portion, and a lower portion;
the semiconductor substrate comprises at least one second opening therein, wherein the at least one second opening comprises a second width and a second depth, wherein the first width is wider than the second width and the first depth is deeper than the second depth;
a first layer within both the at least one first opening and the at least one second opening, wherein the first layer fills the at least one second opening and does not fill the at least one first opening, and is located at the upper portion of the at least one first opening and is not located at the lower portion of the at least one first opening; and
a second layer within the at least one first opening and not within the at least one second opening, wherein the second layer is located at both the upper portion of the at least one first opening and the lower portion of the at least one first opening.

18. The semiconductor device of claim 17, further comprising:
the semiconductor substrate comprises at least two first openings therein;
a doped buried layer within the semiconductor substrate, wherein the doped buried layer is directly interposed between the second layer within the at least two first openings therein and the dielectric first layer within the at least one second opening directly overlies the doped buried layer.

19. A semiconductor device, comprising:
a semiconductor substrate having at least one first opening therein, wherein the at least one first opening comprises a first width, a first depth, an upper portion, and a lower portion;
the semiconductor substrate comprises at least one second opening therein, wherein the at least one second opening comprises a second width and a second depth, wherein the first width is wider than the second width and the first depth is deeper than the second depth;
a dielectric layer within both the at least one first opening and the at least one second opening, wherein the dielectric layer fills the at least one second opening and does not fill the at least one first opening, and is located at the upper portion of the at least one first opening and is not located at the lower portion of the at least one first opening; and
a conductive layer within the at least one first opening and not within the at least one second opening, wherein the conductive layer is located at both the upper portion of the at least one first opening and the lower portion of the at least one first opening and the dielectric layer electrically isolates the conductive layer from the upper portion of the first opening.

20. The semiconductor device of claim 19, further comprising:
the semiconductor substrate comprises at least two first openings therein;
a doped buried layer within the semiconductor substrate, wherein the doped buried layer is directly interposed between the conductive layer within the lower portion of the at least two first openings therein and the dielectric layer within the at least one second opening directly overlies the doped buried layer.

21. A method used during the formation of a semiconductor device, comprising:
forming a patterned mask over an underlying layer, wherein the patterned mask comprises a first opening having a first width and a second opening having a second width narrower than the first width;
performing a first etch to simultaneously etch the underlying layer through the first opening to form a first trench having a bottom and a width about the same as the first width and through the second opening to form a second trench having a bottom and a width about the same as the second width; and
prior to forming a second photoresist mask over the underlying layer, etching the bottom of the first trench without etching the bottom of the second trench.

22. A method used during the formation of a semiconductor device, comprising:
forming a patterned mask over an underlying layer, the patterned mask having a first opening having a first width, a second opening having a second width wider than the first width, and a third opening having a third width wider than the second width;
etching the underlying layer to a first depth through the first opening to form a first trench in the underlying layer, through the second opening to form a second trench in the underlying layer, and through the third opening to form a third trench in the underlying layer;
forming a first conformal layer over the underlying layer, wherein the first conformal layer impinges on itself within the first trench, and forms conformally within the second trench and within the third trench;
etching the first conformal layer to form a first plug within the first trench and to form spacers within the second trench and within the third trench, and etching the underlying layer to a second depth deeper than the first depth through the second trench and through the third trench;
forming a second conformal layer over the underlying layer, wherein the second conformal layer is formed over the first plug, impinges on itself within the second trench, and forms conformally within the third trench; and
etching the second conformal layer to form a second plug within the second trench and to form spacers within the third trench, and etching the underlying layer to a third depth deeper than the second depth through the third trench.

23. An electronic system, comprising:
a semiconductor device, comprising:
a semiconductor substrate having at least one first opening therein, wherein the at least one first opening comprises a first width, a first depth, an upper portion, and a lower portion;
the semiconductor substrate comprises at least one second opening therein, wherein the at least one second opening comprises a second width and a second depth, wherein the first width is wider than the second width and the first depth is deeper than the second depth;
a first layer within both the at least one first opening and the at least one second opening, wherein the first layer fills the at least one second opening and does not fill the at least one first opening, and is located at the upper portion of the at least one first opening and is not located at the lower portion of the at least one first opening; and
a second layer within the at least one first opening and not within the at least one second opening, wherein the second layer is located at both the upper portion of the at least one first opening and the lower portion of the at least one first opening; and
a power source adapted to power the semiconductor device.

24. The electronic system of claim 23, wherein the semiconductor device is a processor and the electronic system further comprises:
at least one memory device coupled to the processor through a bus; and
the power source is adapted to power the semiconductor device.

25. The electronic system of claim 23, wherein the semiconductor device is a memory device and the electronic system further comprises:
at least one processor coupled to the memory device through a bus; and
the power source is adapted to power the at least one processor.
